(19) United States
(12) Patent Application Publication
(10) Pub. No.: US 2024/0349454 A1
(43) Pub. Date: Oct. 17, 2024

(54) COOLING DEVICE FOR VIRTUAL REALITY HEADSETS

(71) Applicant: Jie Gui, Shenzhen (CN)

(72) Inventor: Jie Gui, Shenzhen (CN)

(21) Appl. No.: 18/134,471

(22) Filed: Apr. 13, 2023

(51) Int. Cl. H05K 7/20; G02B 27/01; G06F 1/20

(52) U.S. Cl. CPC H05K 7/2039; G02B 27/0176; G06F 1/203; H05K 7/20218; G06F 2200/201

(57) ABSTRACT

A liquid-filled cushion-shaped cooling device designed for virtual reality headsets is disclosed in this patent. The device is designed to lay around the area where the user's facial and virtual reality headset come in contact. The material of the cooling device uses good thermal conductive materials, such as PVC, silicon, etc. and a low-temperature liquid with large heat absorb capacity in the cushion such as gel, ice, water etc. to keep the contact area cool and refreshing while using virtual reality headset which emits heat generated from its own various components. The main cause of heat emission is mainly because the virtual reality device needs to seal the user's face or eyes into a mini space with the virtual reality headset lens in order to achieve an immersive experience, therefore causing poor ventilation in that area and discomfort in long-term contact between the device and facial area. The heat emission of the user's face also leads to more sultriness in that space. The liquid-filled cushion-shaped cooling device aims to address these issues by providing a comfortable and cool environment for the user while using virtual reality headsets. The cushion-shaped cooling device is easy to use and can be easily attached to any virtual reality headset.

### FIELD OF THE INVENTION

The present invention relates to a liquid filled cushion shaped cooling device for virtual reality headset that lays around the area where the user's facial and virtual reality headset equipment come in contact and the said cooling device has good heat absorbing capacity to keep headset area and facial area cool continuously while in use.

### BACKGROUND OF THE INVENTION

Virtual reality (VR) headsets have become increasingly popular in recent years as the technology behind them has advanced. These devices allow users to immerse themselves in a virtual world and interact with their surroundings in ways that were previously impossible. A virtual reality headset is a device that uses technology to simulate a virtual environment for the user. The headset typically includes a screen or screens that display images, and sensors that track the user's movements in order to update the display accordingly. Some headsets also include controllers that allow the user to interact with the virtual environment, such as by manipulating objects or moving through space.

The concept of virtual reality (VR) can be traced back to the 19th century, when stereoscopic photos were used to create 3D images. However, the first VR headset was not developed until the late 1960s, when computer scientist Ivan Sutherland created a device called the “Sword of Damocles.” This headset used a large computer to generate basic wireframe graphics and was not practical for consumer use.

It was not until the 1990s that VR technology became more widely available. In 1995, Nintendo released the Virtual Boy, a gaming console that used a headset to display simple 3D graphics. However, the Virtual Boy was a commercial failure due to its high price and limited game selection.

In the early 2000s, VR technology began to make a comeback with the development of more advanced graphics engines and the miniaturization of electronics. In 2010, Palmer Luckey, a teenager from California, began experimenting with building his own VR headset in his parents' garage. He created a prototype called the “Rift” that used off-the-shelf components and was compatible with popular gaming platforms like the PC.

Luckey launched a Kickstarter campaign to fund the development of the Rift, which quickly gained a following among gamers and VR enthusiasts. In 2014, Luckey founded Oculus VR, a company dedicated to developing high-quality VR hardware and software. The following year, Facebook acquired Oculus for $2 billion, signaling a major investment in the future of VR technology.

Since then, several other companies have entered the VR market, including HTC, Sony, and Samsung. Today, VR headsets are available in a range of styles and price points, from high-end tethered headsets like the Oculus Rift and HTC Vive to standalone headsets like the Oculus Quest and smartphone-based headsets like the Samsung Gear VR.

As VR technology continues to evolve, the possibilities for its use are expanding beyond gaming and entertainment. VR is being used in fields such as education, healthcare, and engineering to provide immersive training experiences and simulations. It is also being used to create virtual tours of real-world locations and historical sites, allowing people to explore and learn about places they might not otherwise have access to.

Overall, the invention of the VR headset has opened up a new realm of possibilities for immersive experiences and is poised to have a significant impact on the way we work, learn, and play in the years to come.

Virtual reality headsets work by creating a sense of immersion in a virtual environment. This is achieved through a combination of hardware and software technologies. The hardware includes the headset itself, which typically includes a high-resolution display and sensors that track the user's movements in real time. The software includes the virtual environment and any applications or games that run within it.

When the user puts on the headset, they are transported into a virtual world that is generated by the software. As the user moves their head and body, the sensors in the headset track those movements and update the virtual environment in real time. This creates a sense of immersion and presence in the virtual world, allowing the user to interact with it as if it were real.

Virtual reality (VR) technology has come a long way in recent years, offering users an immersive and interactive experience in a simulated environment. However, as with any new technology, there are some problems that users may face while using virtual reality headsets and one of the main problem is users feel heat on their face while using virtual reality headsets since the headset itself can generate heat due to the component inside. For example, the display screen, processor, and graphic card can all generate heat, which can be trapped inside the headset and cause discomfort for the user.

In addition, wearing a VR headset can also cause the body to generate heat due to the physical exertion involved in moving around in a virtual environment. Users may also feel hot and sweaty due to the physical discomfort of wearing a heavy or poorly fitting headset for an extended period of time.

Another factor that can contribute to heat buildup is the lack of ventilation inside the headset. If the headset is designed with insufficient airflow, this can cause heat to become trapped inside and make the user feel uncomfortable.

To mitigate these issues, VR headset manufacturers are continually working to improve the design and ventilation of their devices. Some headsets now include built-in fans or other cooling systems to help regulate temperature, while others feature materials that are designed to be more breathable and comfortable for extended use. Users have to adopt several remedial measures to reduce heat buildup while using a VR headset, such as taking regular breaks to allow their body to cool down, adjusting the fit of the headset to ensure proper ventilation, and using a headset that is specifically designed for extended use with features like cushioned padding and lightweight materials.

### SUMMARY OF THE INVENTION

The present invention relates to a cooling device in the form of liquid-filled cushion designed for virtual reality headsets to provide a comfortable and cool experience for the user. The cooling device is designed to lay around the area where the user's facial and virtual reality headset come in contact. The material of the cooling device uses good thermal conductive materials, such as PVC, silicon, etc., and a low-temperature liquid with a large heat absorb capacity in the core of cooling device such as gel, ice, water, etc., to keep the contact area cool and refreshing while using a virtual reality headset which emits heat generated from its own various components.

The main cause of heat emission is mainly because the virtual reality device needs to seal the user's face or eyes into a mini space with the virtual reality headset lens in order to achieve an immersive experience. This causes poor ventilation in that area and discomfort in long-term contact between the device and facial area. The heat emission of the user's face also leads to more sultriness in that space.

In an embodiment of the present invention, the cooling device for virtual reality headset is designed to solve these problems by providing a cooling effect on the contact area. The cooling device is filled with a low-temperature liquid such as gel, ice, water, etc., which has a large heat absorb capacity to keep the contact area cool. The material of the cooling device is made of good thermal conductive materials such as PVC, silicon, etc., to maximize the heat transfer from the user's face to the cushion. This results in a more comfortable and refreshing experience for the user while using a virtual reality headset.

The cooling device is a liquid-filled cushion designed to be placed around the area where the user's facial and virtual reality headset come in contact. It can be easily attached to the virtual reality headset using various methods such as clips, adhesive, or other fastening mechanisms. The cushion can also be designed in various shapes and sizes to fit different types of virtual reality headsets.

In conclusion, the cooling device for virtual reality headsets provides a comfortable and refreshing experience for the user by keeping the contact area cool and reducing discomfort caused by heat emission from the virtual reality device and the user's face. The cushion can be easily attached to the virtual reality headset and designed in various shapes and sizes to fit different types of virtual reality headsets.

As such, those skilled in the art will appreciate that the conception, upon which this disclosure is based, may readily be utilized as a basis for the designing of other structures, methods, and systems for carrying out the several purposes of the present invention. It is important, therefore, that the claims be regarded as including such equivalent constructions insofar as they do not depart from the spirit and scope of the present invention.

### BRIEF DESCRIPTION OF THE ACCOMPANYING DRAWINGS

The aforesaid as well as other objects and advantages of the invention will appear hereinafter from the following description taken in connection with the accompanying drawings in which:

FIG. 1 illustrates an exemplary embodiment of the cooling device for virtual reality headset;

FIG. 2 illustrates an exemplary cross-sectional embodiment of the cooling device for virtual reality headset; and

FIG. 3 illustrates an exemplary embodiment of the cooling device attached to virtual reality headset.

### DETAILED DESCRIPTION OF THE INVENTION

Additional features and advantages of the invention will be outlined in the description which follows, and in part will be obvious from the description, or may be learned by the practice of the invention. These and other features of the present invention will become more fully apparent from the following description or may be learned by the practice of the invention as set forth hereinafter.

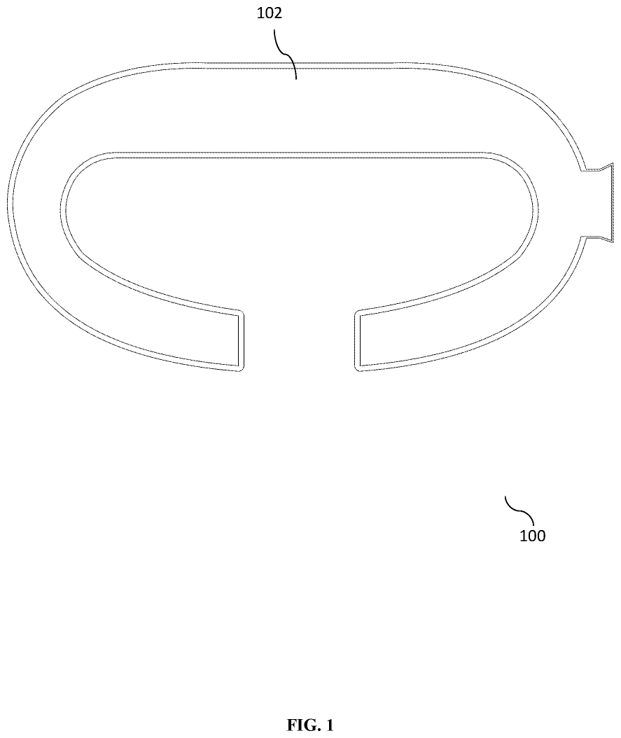

With reference now to the drawings, and in particular, from FIG. 1 to FIG. 3 thereof, a a cooling device for virtual reality headsets embodying the principles and concepts of the present invention is described.

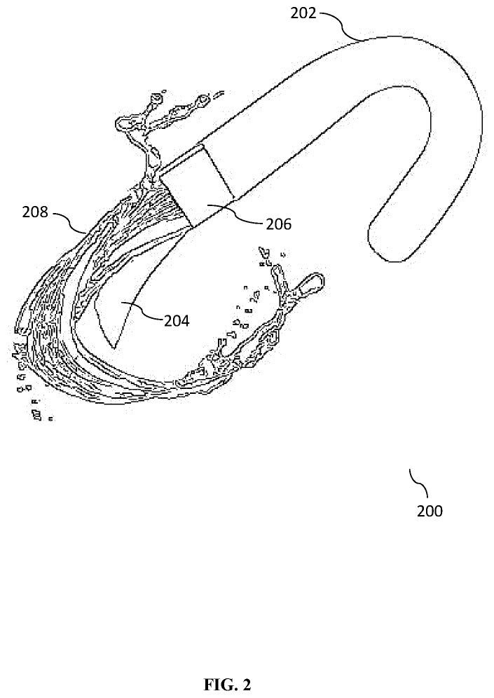

Referring to FIG. 1, an embodiment 100 of the cooling device 102 for virtual reality headsets is disclosed wherein the cooling device is a liquid filled cushion made of material that has good thermal properties designed to lay around the area where the user's facial area and virtual reality headset come in contact. The cooling device 102 for virtual reality headsets is a significant improvement over existing cooling mechanisms or lack of any cooling mechanism in virtual reality headsets. With the thermal conductivity properties of the upper layer and the cooling properties of the low-temperature liquid in the cooling layer as described later in FIG. 2, the cushion ensures that the heat generated by the VR headset is effectively transferred away from the user's facial area, providing a refreshing and comfortable experience. The cooling device's benefits extend beyond just providing comfort to users. It can also potentially reduce the risk of eye strain caused by prolonged use of VR headsets, as the refreshing and cooling properties of the cushion may help relax the user's eye muscles.

The material's thermal conductivity ensures that heat generated by the VR headset is efficiently transferred away from the user's facial area and into the cooling layer. The liquid-filled cooling device is easy to use and can be easily cleaned. The cooling device can be placed around the contact area between the user's facial area and the VR headset. The cooling device adheres to the user's facial area, and the outer layer ensures that it stays in place. The cooling layer absorbs heat generated by the VR headset and dissipates it away from the user's facial area, keeping the contact area cool and refreshing.

Referring to FIG. 2, a cross sectional embodiment 200 of the virtual reality headset cooling device is disclosed wherein the cushion comprises three layers: an upper layer 202 made of good thermal conductive materials, such as PVC, silicon, or any other suitable material, a secondary layer 204 made of a sticky material, and the third layer is cooling layer 206 for keeping liquid in the core cool. The core is filled with a low-temperature liquid 208 with a large heat absorb capacity, including but not limited to gel, ice, water, or any other suitable material.

In an embodiment of the present invention, the upper layer 202 is designed to be in contact with the user's facial skin and the VR headset, and it is made of a material that has good thermal conductivity properties. The material's thermal conductivity ensures that heat generated by the VR headset is efficiently transferred away from the user's facial area and into the cooling layer. The secondary layer is made of a sticky material 204 that adheres to the upper layer and the cooling layer, holding them together. The cooling layer 206 is made of a low-temperature liquid with a large heat absorb capacity, such as gel, ice, water, or any other suitable material. The cooling layer 206 is designed to absorb the heat generated by the VR headset and dissipate it away from the user's facial area, thereby keeping the contact area cool and refreshing. The cooling layer 206 also provides a comfortable and refreshing sensation for the user during prolonged VR sessions. The cooling layer 206 is the final layer of the cushion and serves as a barrier to prevent leaking of low-temperature cooling liquid 208. The cooling layer is made of a material that is impermeable to the low temperature liquid 208 and any other materials used in the cushion's construction.

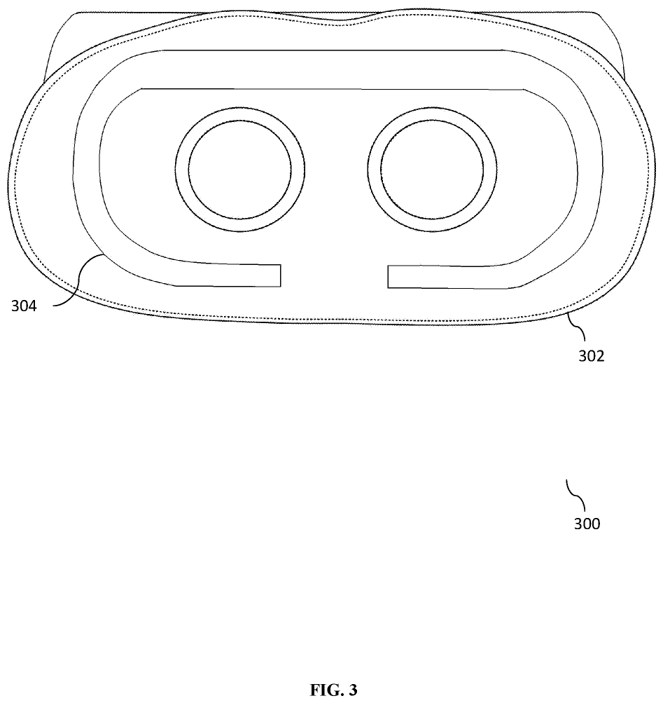

Referring to FIG. 3, an embodiment 300 of cooling device 304 attached to virtual reality headset 302 is disclosed wherein the cooling device 304 is designed to be placed around the area wherein the user's facial and virtual reality headset come in contact. It can be easily attached to the virtual reality headset using various methods such as clips, adhesive, or other fastening mechanisms. The cushion can also be designed in various shapes and sizes to fit different types of virtual reality headsets.

In an embodiment of the present invention, the liquid filled cushion like cooling device 304 is designed to lay around the area where the user's facial and virtual reality headset come in contact. The material of the cooling device uses good thermal conductive materials on outer layer, such as PVC, silicon, etc., and a low-temperature liquid with a large heat absorb capacity in the cushion such as gel, ice, water, etc., to keep the contact area cool and refreshing while using a virtual reality headset which emits heat generated from its own various components.

The main cause of heat emission is mainly because the virtual reality device needs to seal the user's face or eyes into a mini space with the virtual reality headset lens in order to achieve an immersive experience. This causes poor ventilation in that area and discomfort in long-term contact between the device and facial area. The heat emission of the user's face also leads to more sultriness in that space.

The cooling device disclosed in the present invention for virtual reality headsets offers several advantages over conventional cushions or VR headsets that lack any cooling mechanism. Some of these advantages include: comfortable and refreshing sensation for the user during prolonged VR sessions, thereby increasing the user's overall comfort, efficiently absorbing heat generated by the virtual reality headset and dissipate it away from the user's facial area, keeping the contact area cool, versatility to be used with any virtual reality headset and is easy to use and clean, and durability of materials that can withstand prolonged use and frequent cleaning.

In conclusion, the cooling device for virtual reality headsets provides a comfortable and refreshing experience for the user by keeping the contact area cool and reducing discomfort caused by heat emission from the virtual reality device and the user's face. The cooling device can be easily attached to the virtual reality headset and designed in various shapes and sizes to fit different types of virtual reality headsets.

While the exemplary embodiments of the present invention are described and illustrated herein, it will be appreciated that they are merely illustrative. It will be understood by those skilled in the art that various modifications in form and detail may be made therein without departing from or offending the spirit and scope of the invention as defined by the appended claims. Additionally, the invention illustratively disclosed herein suitably may be practiced in the absence of any element which is not specifically disclosed herein—and in particular, embodiment specifically contemplated, is intended to be practiced in the absence of any element which is not specifically disclosed herein.

1. A liquid-filled cooling device for virtual reality headsets, comprising an upper layer made of a thermal conductive material, a secondary layer below the upper layer made of a sticky material, a cooling layer below the secondary layer, and a low-temperature liquid with large heat absorb capacity within the cooling layer.

2. The liquid-filled cooling device of claim 1, wherein the upper layer is made of a material including but not limited to PVC, silicon, and other materials with good thermal conductivity.

3. The liquid-filled cooling device of claim 1, wherein the cooling layer comprises a gel, ice, water or other low-temperature liquid with large heat absorb capacity.

4. The liquid-filled cooling device of claim 1, wherein the cushion is configured to be easily attached to the area where the user's facial area and the virtual reality headset come in contact.

5. The liquid-filled cushion of claim 1, wherein the thermal conductivity of the upper layer and the cooling properties of the low-temperature liquid in the cooling layer effectively transfer heat generated by the virtual reality headset away from the user's facial area.
